(19) United States
(12) Patent Application Publication
(10) Pub. No.: US 2025/0053694 A1
(43) Pub. Date: Feb. 13, 2025

(54) METHOD OF SELECTING A COMPONENT IN A CAD MODEL

(71) Applicant: Siemens Industry Software Inc., Plano, TX (US)

(72) Inventor: David Kennett, Cambridge (GB)

(21) Appl. No.: 18/718,236

(22) PCT Filed: Dec. 10, 2021
(86) PCT No.: PCT/US2021/062803

§ 371 Date: Jun. 10, 2024

(51) Int. Cl. G06F 30/12

(52) U.S. Cl. CPC G06F 30/12

(57) ABSTRACT

A computer-implemented method of enabling a user to select at least one component from a group including identical and/or non-identical components forming part of a computer-aided design (CAD) model is provided. The method includes: a) receiving a seed component selection from a user via a user input device, where the seed component represents component criteria desired by the user; and b) based on the seed component, generating a selection including at least one component sharing common shape elements with the seed component. The HDBSCAN algorithm is used to cluster together components within a CAD application. The clustered components are then displayed to a user based on the seed component. This enables a user to select similar components quickly and simply.

This application is the National Stage of International Application No. PCT/US2021/062803, filed Dec. 10, 2021. The entire contents of this document are hereby incorporated herein by reference.

### BACKGROUND

The present embodiments relate to a computer-implemented method of enabling a user to select at least one component from a group including identical and/or non-identical components forming part of a computer-aided design (CAD) model.

Computer-Aided Design (CAD) systems are used commonly in many fields of engineering, manufacturing, and design to create and manipulate solid modelling representations of objects, for example, in additive manufacturing. Boundary representation (B-rep) technology dominates CAD modelling. The B-rep technology provides an efficient and adaptable representation of parts by combining classic geometry, analytic surfaces and curves, non-uniform rational basis spline (NURBS), and procedural surfaces and curves, with topology, which captures the connectivity and interaction between geometric elements. Additive manufacturing is the process of creating three-dimensional objects using a three-dimensional printer based on CAD or other digital three-dimensional models. Objects may be scanned as a precursor to creating a CAD model, or may be designed from scratch, and stored in either sterolithography file format (STL) or additive manufacturing file format (AMF) files for future printing.

As part of the design of an assembly model, a user may choose to create or use components that are the same or similar to other components within the context of the main assembly. Finding components that are an exact match is a relatively simple process; however, this is not necessarily the case for similar components. Similar components are those that share common shape elements with another component. Such common shape elements are component attributes, such as size, geometry, features, function, color, or texture. For example, a user may be designing a vehicle, which requires a nut and bolt assembly to hold two components together. As part of the design process, the user may have already used a similar nut and bolt assembly, and so now wishes to find an appropriate, but similar, nut and bolt pairing in order to complete this aspect of the design. Typically, the user is to rely on recognizing similar components visually, consistent use of naming standards, categorizations, or other classifications, and/or consistent language in order to determine similarity. While this may be a simple task if all of these aspects are present, or there is only a limited number of components in use, as designs become increasingly large or complex, the task becomes increasingly difficult. One possibility is to restrict searches to outside of the CAD application to find a similar component to add to a product. If working within the CAD application, the user may select components within the graphics screen or from a representation of the bill of materials of the components on which the user wishes to operate. It is also possible to create, in advance, sets of components based on attributes that a user deems to indicate that one component is similar to another found within libraries of identical and non-identical components. For example, a user may create sets of bolts, nuts, and screws in advance of working within the CAD application on a product. However, this relies on the user being able to spend time in advance of working to select such similar components from large libraries available with typical CAD software, and that the user is able to predict in advance the range of similarities or uses of components that will be required for modelling various products. One further issue is that the selection is limited by this advance preparation, thus removing the ability to predict and offer alternative similar products to a user during the design process. It would be useful, therefore, to be able to provide CAD applications with the ability to identify similar components on-the-fly during the design process.

### SUMMARY AND DESCRIPTION

The embodiments aim to address these issues by providing, in a first aspect, a computer-implemented method of enabling a user to select at least one component from a group including identical and/or non-identical components forming part of a computer-aided design (CAD) model. The method includes the acts of: a) receiving a seed component selection from a user via a user input device, the seed component representing component criteria desired by the user; and b) based on the seed component, generating a selection including at least one component sharing common shape elements with the seed component. The act of generating a selection includes: i) clustering the group of identical and/or non-identical components into clusters Cₙ using a first hyperparameter value kₘ₌₁, where kₘϵ [symbol] and kₘ≠1, in a clustering algorithm. Each cluster Cₙ has a stability Sₙ and a component density λₙ. The clustering algorithm is a hierarchical clustering algorithm and generates an initial dendrogram of clusters based on the hyperparameter kₘ. Each node in the dendrogram represents a cluster of components. The act of generating a selection also includes: ii) selecting a subset of clusters Cₘ by flattening the dendrogram to produce a non-overlapping clustering; and iii) calculating a validity index ψ₁ for the first hyperparameter k₁. The validity index ψ₁ is proportional to the sum over the subset of clusters of the integral of 1/λ over each of the components in each of the selected clusters. The act of generating a selection also includes: iv) generating a set of clusterings {Cₘ} for a set of m values of the hyperparameter kₘ and the associated validity indexes by repeating acts i) to iii); v) choosing the clustering for which kₘ=argmaxₘ({ψₘ}) as the basis of a selection including at least one component sharing common shape elements with the seed component; and vi) matching a cluster from the clustering to the seed component for display as the selection comprising at least one component sharing common shape elements with the seed component.

By utilizing a hierarchical clustering algorithm approach, it is possible to enable a user to quickly and simply select similar components for further processing within a CAD application. There is no need to limit such selection to identical components or to require the pre-selection of libraries or place any limitations on categorization, language, or other identification of components, since the use of a hyperparameter optimization approach within a clustering algorithm obviates such steps.

In one embodiment, the act ii) of selecting a subset of clusters includes: condensing the initial dendrogram of clusters Cₙ into a simplified dendrogram having a reduced number of clusters Cᵣ; and flattening the dendrogram to select the subset of clusters Cₘ using an excess of mass algorithm. The reduced number of clusters is determined by a minimum cluster size J indicating the minimum number j of components within each cluster.

In one embodiment, the stability Sᵣ of a cluster Cᵣ in the reduced clustering is given by:

$${S}_{r} = {\sum }_{{c}_{j} ϵ {C}_{r}} ( {λ}_{max} ( {c}_{j} , {C}_{r} ) - {λ}_{min} ( {C}_{r} ) )$$

where λₘₐₓ(cⱼ, Cᵣ) is the density level beyond which a component cⱼ is no longer part of the cluster Cᵣ, and λₘᵢₙ(Cᵣ) is the minimum density level at which the cluster Cᵣ exists.

In one embodiment, the act iii) of calculating a validity index Um includes calculating:

$${ψ}_{m} = \frac{1}{NH} {\sum }_{p ϵ {C}_{m}} ( {\sum }_{j {ϵΦ}_{p}} {ε}_{j} )$$

where Φₚ represents a dendrogram node that corresponds to a cluster in Cₘ, N is the number of components in the group, H is the height of the dendrogram, and εⱼ=1/λⱼ for each of the j components in a cluster.

In one embodiment, the hierarchical clustering algorithm is HDBSCAN.

The method may further include the act of displaying the seed component and/or the selection including at least one component sharing common shape elements with the seed component to the user. In addition, the method may further include the act of filtering the seed component and/or the selection based on an independent filter prior to displaying to the user. In one embodiment, displaying the seed component and/or at least one component takes place via a graphical control element displayed to the user.

Displaying the selection of at least one component may include pre-populating the graphical control element. The method may further include the acts of: c) receiving a confirmation of the selection of at least one component by the user; and d) adding the selected at least one component to a selection list for further operations within the CAD model.

Alternatively, the method may further include the act of: c) adding the selected at least one component to a selection list for further operations within the CAD model.

In one embodiment, the shapes of the components are described as n-dimensional vectors.

In a second aspect, embodiments also provide a computer program product including instructions that, when run on a computer, cause the computer to execute the acts of the method above.

In a third aspect, embodiments further provide a data-processing system configured to enable a user to select at least one component from a group including identical and/or non-identical components forming part of a computer-aided design (CAD) model. The data-processing system includes: a user input device configured to receive a seed component selection from a user, the seed component representing component criteria desired by the user. A processor is configured to generate, based on the seed component, a selection including at least one component sharing common shape elements with the seed component. The processor being configured to generate a selection includes the processor being configured to: i) cluster the group of identical and/or non-identical components into clusters Cₙ using a first hyperparameter value kₘ₌₁, where kₘϵ [symbol] and kₘ≠1, in a clustering algorithm. Each cluster Cₙ has a stability Sₙ and a component density λₙ. The clustering algorithm is a hierarchical clustering algorithm and generates an initial dendrogram of clusters based on the hyperparameter kₘ, where each node in the dendrogram represents a cluster of components. The processor being configured to generate a selection also includes the processor being configured to: ii) select a subset of clusters Cₘ by flattening the dendrogram to produce a non-overlapping clustering; calculate a validity index ψ₁ for the first hyperparameter k₁, where the validity index ψ₁ is proportional to the sum over the subset of clusters of the integral of 1/λ over each of the components in each of the selected clusters; iii) select a set of clusterings {Cₘ} for a set of m values of the hyperparameter kₘ and the associated validity indexes by repeating acts i) to iii); iv) choose the clustering for which kₘ=argmaxₘ({ψₘ}) as the basis of a selection including at least one component sharing common shape elements with the seed component; and v) match a cluster from the clustering to the seed component for display as the selection including at least one component sharing common shape elements with the seed component.

In one embodiment, the data-processing system further includes a display configured to display the seed component and/or selection of at least one component to the user.

### BRIEF DESCRIPTION OF THE DRAWINGS

FIG. 1 is a schematic diagram showing the core distance between a point a and its kth neighbor (where k=5) for a distribution of point;

FIG. 2a is an example of a full dendrogram;

FIG. 2b is an example of a condensed dendrogram;

FIGS. 3a to 3j are validity index/hyperparameter plots and point distributions from the Sklearns datasets;

FIGS. 4a to 4d are examples of simple 3-dimensional datasets with clustering;

FIG. 4e is a validity index/hyperparameter plot for the datasets of FIGS. 4a to 4d;

FIGS. 5a to 5d are examples of three-dimensional component datasets with clustering;

FIG. 5e is a validity index/hyperparameter plot for the datasets of FIGS. 5a to 5d;

FIGS. 6a to 6c are examples of random 3-dimensional datasets with clustering;

FIG. 6d is a validity index/hyperparameter plot for the datasets of FIGS. 6a to 6c;

FIG. 7 is a flowchart showing the acts of a method in accordance with embodiments; and

FIG. 8 illustrates an example of a data processing system in which an embodiment of the present disclosure may be implemented.

### DETAILED DESCRIPTION

In the description below, the following notations are used:
kₘ—hyperparameter value k having a value of m, where kₘϵ [symbol] and kₘ≠1;
Cₙ—clusters of data points, such as components, in a full dendrogram;
Cₘ—a selected subset of clusters of data points, such as components, from a reduced or simplified dendrogram for a value of the hyperparameter k of m;
Cᵣ—clusters of data points, such as components, in a reduced or simplified dendrogram;
Sₙ—stability of the nth cluster in the dendrogram;
λₙ—point or component density within the n^{th} cluster;
ψₘ—stability index for the hyperparameter k=m value;
{Cₘ}—set of m clusterings corresponding to m values of the hyperparameter k;
ε—1/λ;
d_{mreach-k}(a,b)—mutual reachability distance;
core (a), coreₖ(b)—a distance from a (or b) to the kth nearest neighbor, where k is a positive integer and greater than 1 (kϵ [symbol] and k≠1);
d(a,b)—original metric distance between points a and b;
J—a minimum cluster size for a dendrogram, where [symbol] ϵ [symbol] and J≠1;
Φₚ—dendrogram node corresponding to a cluster in Cₘ;
N—number of points or components in the group for which the value of the hyperparameter k is being optimized;
H—height of the reduced or simplified dendrogram;
Σ_{jϵΦ}_{ₚ} εⱼ is the sum of all εⱼ over j in the dendrogram node Φ; and
Σ_{pϵC}_{ₘ}(Σ_{jϵΦ}_{ₚ} εⱼ) is the sum of this sum over all nodes p in the dendrogram having clusters Cₘ for the m^{th} value of the hyperparameter k.

The embodiments take the approach that unsupervised machine learning may be used to identify similar parts that may be presented quickly and easily to a user working on a design within a CAD application. Rather than the relying on user recognition, classification, or advance preparation, the embodiments described below start by receiving a seed component selection from a user via a user input device. This may be a component selected from a list by the user, or by clicking on a part or component within the design the user is working on. The seed component represents component criteria desired by the user, such as the size, geometry, features, function, color, or texture of the component. Based on the seed component, a selection including at least one component sharing common shape elements with the seed component is then generated. This includes initially clustering the group of identical and/or non-identical components into clusters Cₙ using a first hyperparameter value kₘ₌₁, where kₘϵ [symbol] and kₘ≠1, in a clustering algorithm. Each cluster Cₙ has a stability Sₙ and a component density λₙ. The clustering algorithm is a hierarchical clustering algorithm, such as HDBSCAN, and generates an initial dendrogram of clusters based on the hyperparameter kₘ. Each node in the dendrogram represents a cluster of components. A subset of clusters Cₘ is then selected by flattening the dendrogram to produce a non-overlapping clustering. A validity index Φ₁ is calculated for the first hyperparameter k₁. The validity index vi is proportional to the sum over the subset of clusters of the integral of 1/λ₁ over each of the components in each of the selected clusters. The value 1/λ is also known as ε, used as the cut-off point when considering clustering using an algorithm such as HDBSCAN. Next, a set of clusterings {Cₘ} for a set of m values of the hyperparameter kₘ is generated by repeating the clustering and validity index calculations. The clustering for which kₘ=argmaxₘ({ψₘ}) is chosen as the basis of a selection including at least one component sharing common shape elements with the seed component. A cluster from the clustering is matched to the seed component for display as the selection including at least one component sharing common shape elements with the seed component. The embodiments that deal with this selection in more detail will be outlined further below.

Rather than using a machine learning algorithm that requires a training step, the embodiments described below utilize clustering, which is a subset of machine learning that works with datasets that are not labelled. As the data is not labelled, the machine learning is to find patterns and relationships between the data samples, and group data samples together. Similar datasets are able to form clusters, hence the term “clustering”. Clustering algorithms are instance-based, providing that the dataset is kept for all uses of the algorithm, since there is no way in which a model may be defined from the data beforehand.

For clustering to be able to take place, the data used should be vectorized, such that a parameter of interest is describable as a numerical vector. For example, vectors obtained from Geolus Profile-G in the NX CAD software available from Siemens Industry Software, Inc. (https://www.sw.siemens.com/en-US/) are thirty-dimensional vectors and used in the embodiments described below. However, any form of vectorization that meets the criteria of the design of the user may be used instead. The embodiments utilize the hierarchical density-based spatial clustering of applications with noise (HDBSCAN) clustering algorithm, originally published in “Density-Based Clustering Based on Hierarchical Density Estimates” by R. Campello, D. Moulavi and J. Sander, Advances in Knowledge Discovery and Data Mining, pp 160-172, Berlin, Heidelberg: Springer Berlin Heidelberg, 2013.

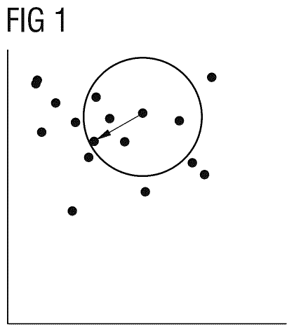

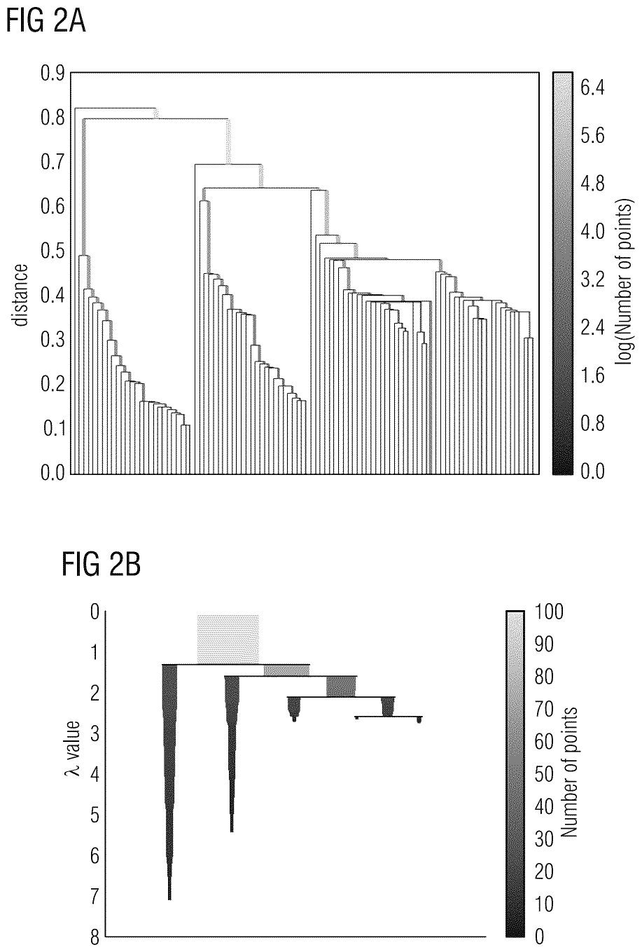

As a simplified explanation, in HDBSCAN, a hierarchy is constructed from a minimum spanning tree for a group of points based on the concept of the mutual reachability distance (MRD):

$${d}_{mreach - k} ( a , b ) = max \{ {core}_{k} ( a ) , {core}_{k} ( b ) , d ( a , b ) \} \qquad Equation 1$$

where the core distance for a hyperparameter k for a point a (coreₖ(a)) is the distance from a to the kth nearest neighbor, where k is a positive integer and greater than 1 (kϵ [symbol] and k≠1) such that a low core distance value indicates a high density of points and a high core distance value indicates a low density of points; (coreₖ(b)) is the core distance for a hyperparameter k for a point b; (coreₖ(b)) is the distance from b to the kth nearest neighbor; d(a,b) is the original metric distance between the points a and b. This is illustrated in FIG. 1, which is a schematic diagram showing the core distance between a point a and its k^{th} neighbor (where k=5) for a distribution of points. The core distance may be determined for each point in the distribution, allowing a minimum spanning tree to be built using an algorithm such as Prim's algorithm. The minimum spanning tree may then be converted into a hierarchy of connected components and viewed as a dendrogram by sorting the edges of the tree by distance in increasing order and iterating through, creating a new cluster for each edge, taking care to identify the two clusters that each edge will join together. An example of a full dendrogram is illustrated in FIG. 2a, which is then condensed by the HDBSCAN algorithm to a condensed dendrogram, as illustrated in FIG. 2b, by introducing the concept of minimum cluster size. A second hyperparameter J, where Jϵ [symbol] and J≠1, represents the smallest size of cluster to be considered by the algorithm. The value of the hyperparameter k may be the same as the value of the hyperparameter J denoting the minimum cluster size.

The dendrogram is flattened to produce a non-overlapping clustering Cₘ, resulting in a selection of a subset of the original clusters shown in FIGS. 2a and 2b. For the reduced clusters Cᵣ, the stability will be given by

$${S}_{r} = {\sum }_{{c}_{j} ϵ {C}_{r}} ( {λ}_{max} ( {c}_{j} , {C}_{r} ) - {λ}_{min} ( {C}_{r} ) ) \qquad Equation 2$$

where λₘₐₓ(cⱼ, Cᵣ) is the density level beyond which a component cⱼ is no longer part of the cluster Cᵣ, and λₘᵢₙ(Cᵣ) is the minimum density level at which the cluster Cᵣ exists. This is a measure of the persistence of a cluster, indicating whether a cluster has split into sub-clusters at any point. For example, if we consider a single point within a cluster, this point may remain in the same cluster for the whole of the lifetime of the cluster or may be included in a sub-cluster when this is split off from the main cluster. Alternatively, there may be another instance in the lifetime of the cluster at which the point leaves the cluster. Rather than taking the top-down approach as with the minimum spanning tree, this is determined by examining the dendrogram from the bottom up. One way of doing this is to consider the sum of stabilities of two sub-clusters that join to form a single parent cluster, which may be lesser or greater than the stability of the parent. By taking the approach that each node in the dendrogram represents a cluster, it is possible to carry out this assessment for each node, such that for a particular hyperparameter k, a reduced subset of clusters may be chosen. However, the choice of hyperparameter k, and therefore also the hyperparameter J, is not a simple matter, since the clusterings are to make sense. For any arrangement of points, there is therefore an optimized value of the hyperparameter k that is to be determined, since the clusterings found will be optimized at this value of k. Therefore, it is necessary to find a method to compare the m possible clusterings {Cₘ} generated from the m values of the hyperparameter kₘ that may be chosen in order to determine an optimized value for the hyperparameter kₘ.

Directly comparing the values of cluster stability for dendrograms generated using different hyperparameters kₘ to determine the optimum value of the hyperparameter k would merely result in the lowest value of the hyperparameter k each time. Therefore, a validity index Um may be created for each value of the hyperparameter kₘ,

$${ψ}_{m} = \frac{1}{NH} {\sum }_{p ϵ {C}_{m}} ( {\sum }_{j {ϵΦ}_{p}} {ε}_{j} ) \qquad Equation 3$$

where Øp represents a dendrogram node that corresponds to a cluster in Cₘ, N is the number of components in the group, H is the height of the dendrogram and εⱼ=1/λⱼ for each of the j components in a cluster. Σ_{jϵΦ}_{ₚ} εⱼ is the sum of all εⱼ over j in the dendrogram node Pp, and Σ_{pϵC}_{ₘ} (Σ_{jϵΦ}_{ₚ} εⱼ) is the sum of this sum over all nodes p in the dendrogram having clusters Cₘ for the mth value of the hyperparameter k. The use of N and H is to normalize the value of ψₘ, removing the contribution of points representing noise from the summation and confining any effects due to this to the normalization. Effectively, the right-hand side of equation 3 represents a sum over the points in a node of the dendrogram, so over the points in a cluster, and the left-hand side represents the sum over all of the stable nodes from the condensed dendrogram. By calculating the validity index Um for a range of hyperparameter k values for a particular data set and plotting the validity index against the hyperparameter k value, the optimum value of the hyperparameter k from the m values chosen will be the maximum point on the graph. In other words, the optimized hyperparameter kₘ value is given by

$${k}_{m} = arg {max}_{m} ( \{ {ψ}_{m} \} ) \qquad Equation 4$$

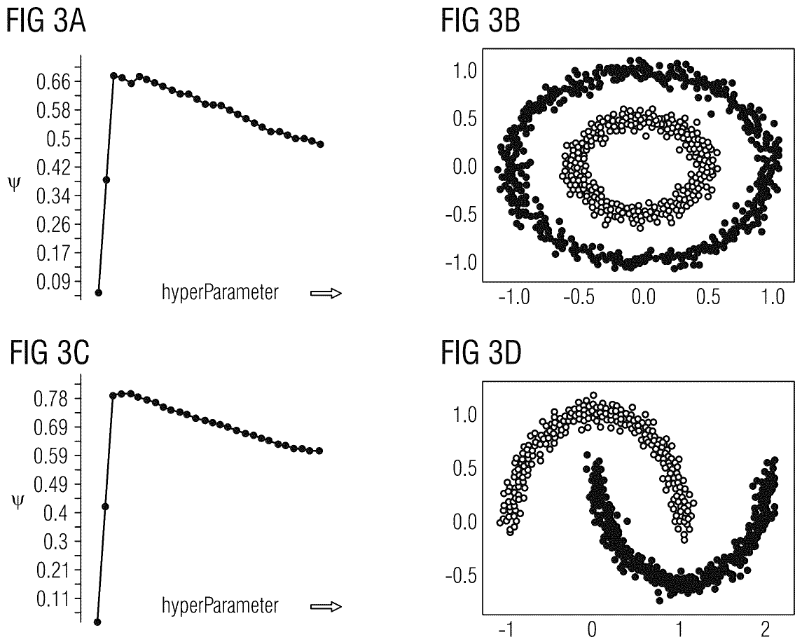

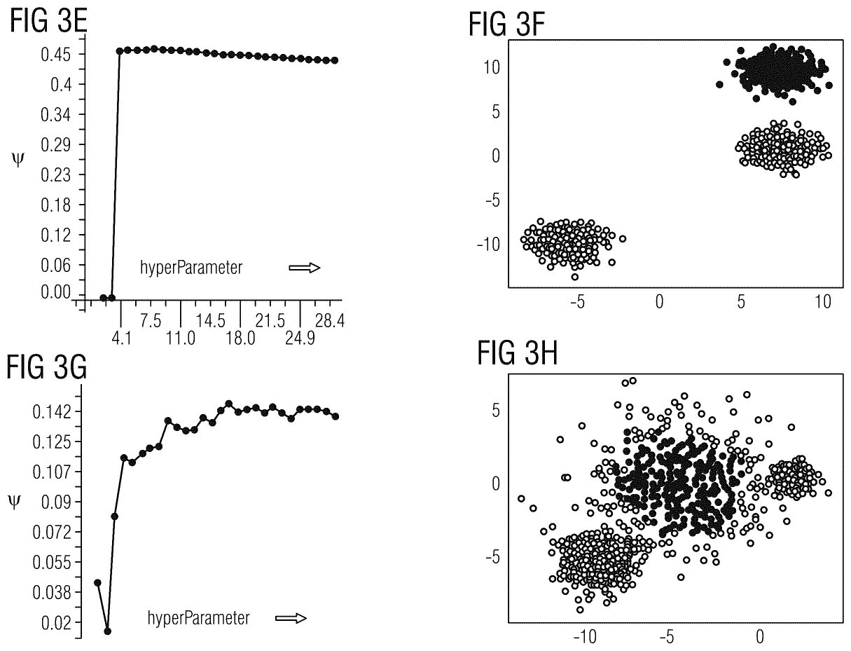

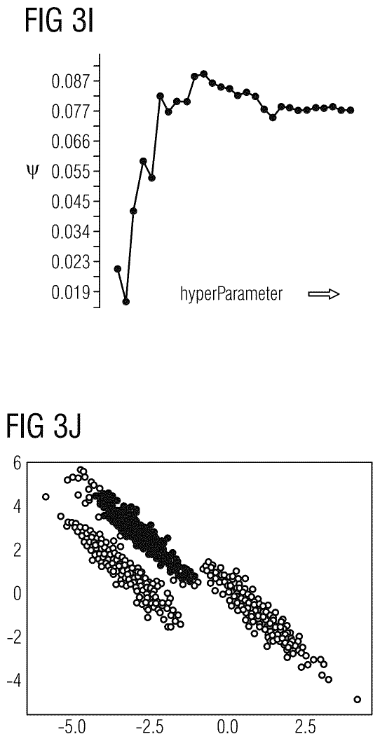

This is illustrated further for 2-dimensional datasets in FIGS. 3a to 3j. In order to demonstrate this approach, a number of datasets from the Sklearn “toy” dataset were used (https://scikit-lean.org/stable/auto_examples/cluster/plot_cluster_comparison.html) to compare the optimized k value determined using the validity index approach and given for each dataset. FIG. 3a is an index plot of the validity index ψ against hyperparameter k for the “noisy circles” dataset, and FIG. 3b is the plot of the “noisy circles” dataset. The optimum value of the hyperparameter k given with the dataset is 4, and FIG. 3a shows that the maximum validity index value is at k=4. FIG. 3c is an index plot of the validity index ψ against hyperparameter k for the “noisy moons” dataset, and FIG. 3d is the plot of the “noisy moons” dataset. The optimum value of the hyperparameter k given with the dataset is 6, and FIG. 3d shows that the maximum validity index value is at k=6. FIG. 3e is an index plot of the validity index ψ against hyperparameter k for the “blobs” dataset, and FIG. 3f is the plot of the “blobs” dataset. The optimum value of the hyperparameter k given with the dataset is 8, and FIG. 3f shows that the maximum validity index value is at k=8. FIG. 3g is an index plot of the validity index ψ against hyperparameter k for the “varied” dataset, and FIG. 3h is the plot of the “varied” dataset. The optimum value of the hyperparameter k given with the dataset is 17, and FIG. 3g shows that the maximum validity index value is at k=17. FIG. 3i is an index plot of the validity index ψ against hyperparameter k for the “aniso” dataset, and FIG. 3j is the plot of the “aniso” dataset. The optimum value of the hyperparameter k given with the dataset is 12, and FIG. 3h shows that the maximum validity index value is at k=12.

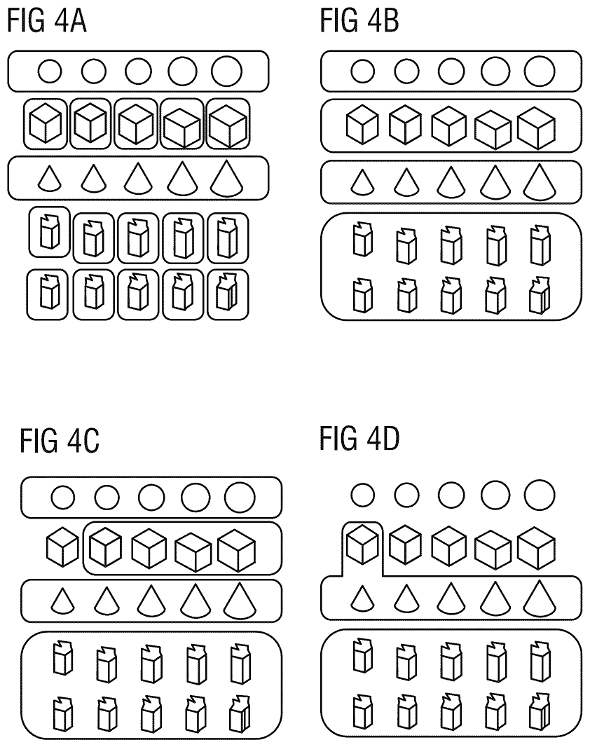

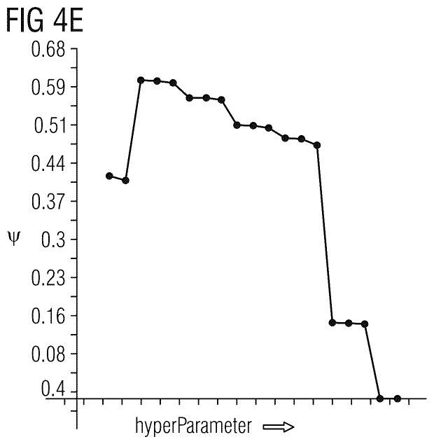

This principle may also be extended to datasets of 3-dimensional shapes, such as components in a CAD application. FIGS. 4a to 4d are an example dataset of seventy-five 3-dimensional shapes illustrating different clusterings (of which only twenty-five are shown for clarity). Using the HDBSCAN algorithm method outlined above, clusterings were generated using four different values of the hyperparameter k (and therefore the hyperparameter J). FIG. 4a illustrates the clustering generated using a hyperparameter k value of 2/3, FIG. 4b illustrates the clustering generated using a hyperparameter k value of 4, FIG. 4c illustrates the clustering generated using a hyperparameter k value of 9, and FIG. 4d illustrates the clustering generated using a hyperparameter k value of 16. Visually, the most appropriate clustering appears to be that from a hyperparameter k value of 4, since this clearly clusters together spheres with spheres, cuboids with cuboids, cones with cones, and complex polyhedral shapes with complex polyhedral shapes. The results from the other values of the hyperparameter k either exclude individual shapes (k=9) or cluster together non-alike shapes (k=16). Components that are not grouped into a cluster (such as in FIGS. 4c and 4d) are considered to be noise. Although not all of the components are shown for clarity, some clusters will include components from those not illustrated. FIG. 4e is a graph of validity index against hyperparameter k value for the dataset shown in FIGS. 4a to 4d. By using Equation 4 to determine the optimum value for the hyperparameter k and comparing with FIG. 4e, the optimum may be k=4. This fits with the visual interpretation based on FIG. 4b.

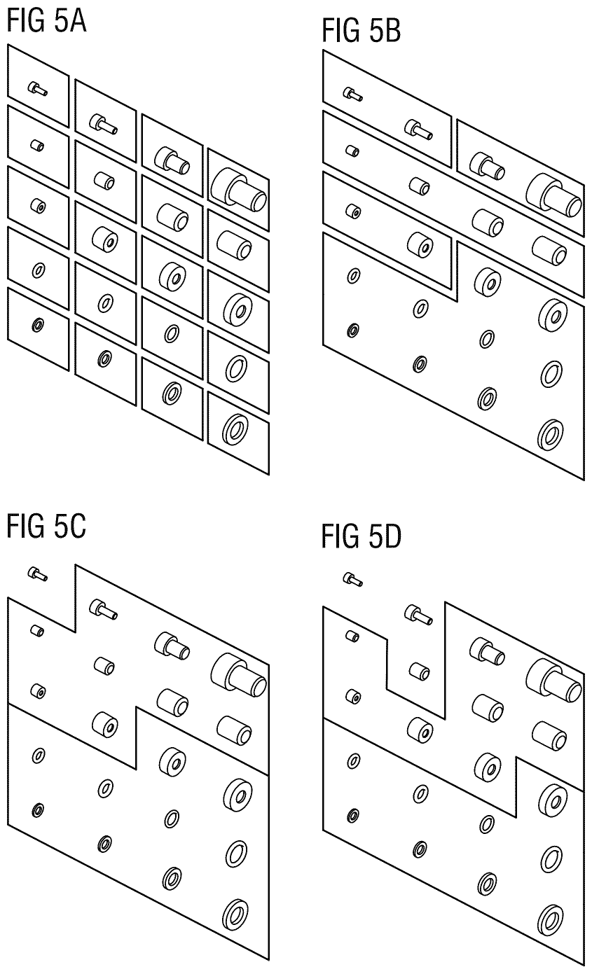

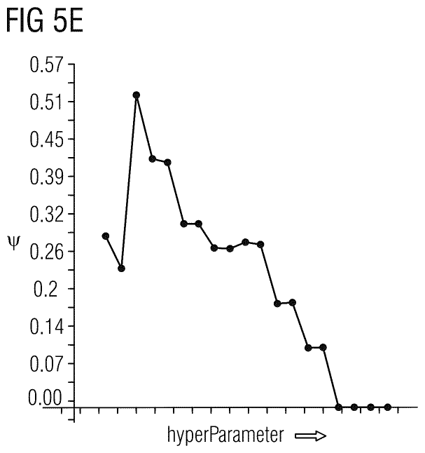

FIGS. 5a to 5d show an example dataset of forty three-dimensional shapes illustrating different clusterings (of which only twenty are shown for clarity). The three-dimensional shapes were generated using the NX CAD application. Using the HDBSCAN algorithm method outlined above, clusterings were generated using four different values of the hyperparameter k (and therefore the hyperparameter J). FIG. 5a illustrates the clustering generated using a hyperparameter k value of 2, FIG. 5b illustrates the clustering generated using a hyperparameter k value of 4, FIG. 5c illustrates the clustering generated using a hyperparameter k value of 6, and FIG. 5d illustrates the clustering generated using a hyperparameter k value of 14. Visually, the most appropriate clustering appears to be that from a hyperparameter k value of 4, since this clearly clusters together small bolts with small bolts, large bolts with large bolts, small washers with small washers, and large washers with large washers. The results from the other values of the hyperparameter k either exclude individual shapes (k=6) and both exclude like shapes and cluster together non-alike shapes (k=16). Components that are not grouped into a cluster (such as in FIGS. 5c and 5d) are considered to be noise. Although not all of the components are shown for clarity, some clusters will include components from those not illustrated. FIG. 5e is a graph of validity index against hyperparameter k value for the dataset shown in FIGS. 5a to 5d. By using Equation 4 to determine the optimum value for the hyperparameter k and comparing with FIG. 5e, the optimum may be k=4. This fits with the visual interpretation based on FIG. 5b.

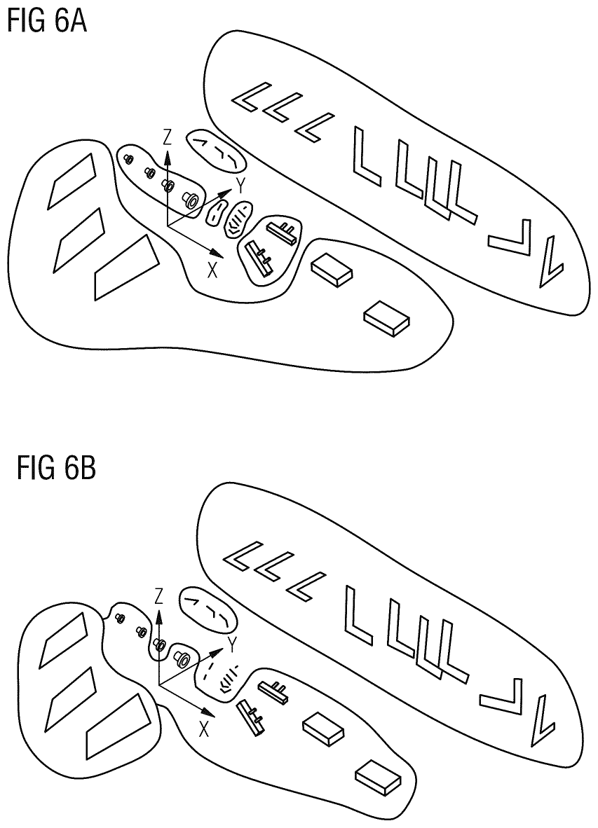

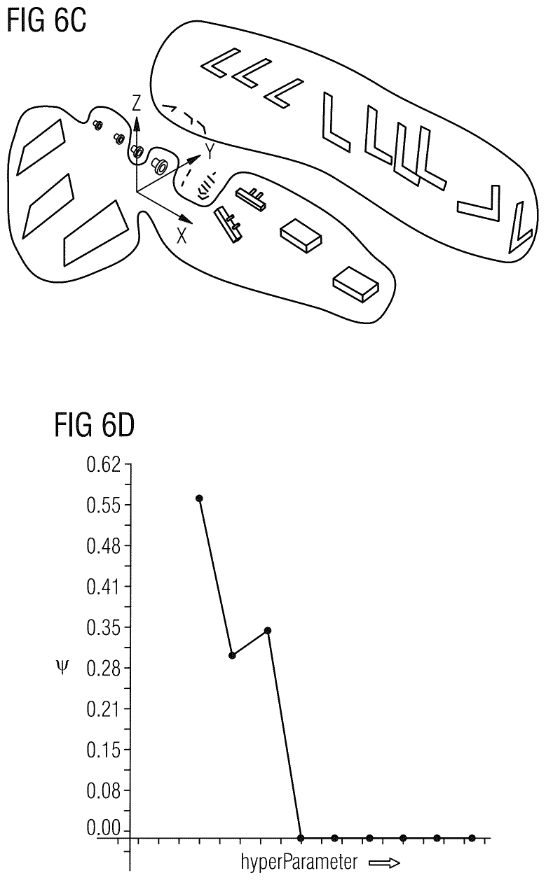

FIGS. 6a to 6c are an example dataset of twenty-six random 3-dimensional shapes illustrating different clusterings. Using the HDBSCAN algorithm method outlined above, clusterings were generated using three different values of the hyperparameter k (and therefore the hyperparameter J). FIG. 6a illustrates the clustering generated using a hyperparameter k value of 2, FIG. 6b illustrates the clustering generated using a hyperparameter k value of 3, and FIG. 6c illustrates the clustering generated using a hyperparameter k value of 4. The results from the other values of the hyperparameter k exclude various components from the clusterings. FIG. 6d is a graph of validity index against hyperparameter k value for the dataset shown in FIGS. 6a to 6c. By using Equation 4 to determine the optimum value for the hyperparameter k and comparing with FIG. 6d, it may be seen that the optimum is k=2. This fits with the visual interpretation based on FIG. 6a, and all other values of the hyperparameter k beyond 4 would be entirely noise.

Methods in accordance with the embodiments based on the use of the HDBSCAN algorithm outlined above will now be described in more detail. The validity index ψ may be used to determine whether or not components are similar to a seed component chosen by a user. The clustering method itself is used to cluster together groups of similar components, based upon the optimization of the hyperparameter k value, and the seed component is then used to choose the relevant clustering.

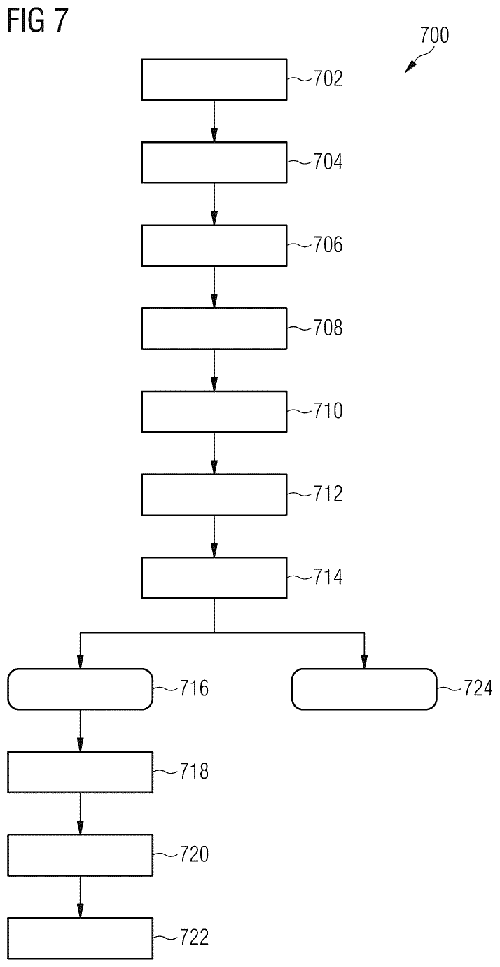

FIG. 7 is a flowchart showing the acts of a method in accordance with embodiments. Initially, the method 700 begins at act 703 with receiving a seed component selection from a user via a user input device. The seed component represents component criteria desired by the user. Components are grouped in a group including identical and/or non-identical components forming part of the computer-aided design (CAD) model. Component criteria include the shape elements of a component desired by the user, such as the shape of a bolt or a washer. At act 704, the process of generating a selection including at least one component sharing common shape elements with the seed component begins with clustering the group of identical and/or non-identical components into clusters Cₙ using a first hyperparameter value kₘ₌₁, where kₘϵ [symbol] and kₘ≠1. The hyperparameter k value is used in a clustering algorithm, where each cluster Cₙ has a stability Sₙ and a component density λₙ The clustering algorithm is a hierarchical clustering algorithm, such as HDBSCAN, as discussed above, and generates an initial dendrogram of clusters based on the hyperparameter kₘ. Each node of this initial dendrogram represents a cluster of components. Next, at act 706, a subset of clusters Cₘ is selected by flattening the dendrogram to produce a non-overlapping clustering. This is done by condensing the initial dendrogram of clusters Cₙ into a simplified dendrogram having a reduced number of clusters Cᵣ, and flattening the dendrogram to select the subset of clusters Cₘ using an excess of mass algorithm. The reduced number of clusters is determined by a minimum cluster size J indicating the minimum number j of components within each cluster, as above. At act 708, a validity index ψ₁ is calculated for the first hyperparameter k₁, where the validity index ψ₁ is proportional to the sum over the subset of clusters of the integral of 1/λ over each of the components in each of the selected clusters. The calculation of the validity index ψ₁ is based upon Equation 3 above, where initially, the stability Sᵣ of a cluster Cᵣ in the reduced number of clusters of the simplified dendrogram is calculated using:

$${S}_{r} = {\sum }_{{c}_{j} ϵ {C}_{r}} ( {λ}_{max} ( {c}_{j} , {C}_{r} ) - {λ}_{min} ( {C}_{r} ) )$$

where λₘₐₓ(cⱼ, Cᵣ) is the density level beyond which a component cⱼ is no longer part of the cluster Cᵣ, and λₘᵢₙ(Cᵣ) is the minimum density level at which the cluster Cᵣ exists, as in Equation 2 above. Once Sᵣ is calculated, the validity index ψ₁ for the first hyperparameter kₘ₌₁ value is calculated:

$${ψ}_{m} = \frac{1}{NH} {\sum }_{p ϵ {C}_{m}} ( {\sum }_{j {ϵΦ}_{p}} {ε}_{j} )$$

where Φₚ represents a dendrogram node that corresponds to a cluster in Cₘ, N is the number of components in the group, H is the height of the dendrogram, and εⱼ=1/λⱼ for each of the j components in a cluster.

Once this first validity index ψ₁ has been calculated, at act 710, a set of clusterings {Cₘ} for a set of m values of the hyperparameter kₘ and the associated indexes are generated by repeating acts 704 to 708. At act 712, the clustering for which kₘ=argmaxₘ({ψₘ}) is provided as the basis of a selection including at least one component sharing common shape elements with the seed component. This part of the method 700 then completes at act 714 by matching a cluster from the clustering to the seed component for display as the selection including at least one component sharing common shape elements with the seed component.

At this point, the CAD application is then able to take two routes: the first being to enable the user of the CAD application to confirm the selection is correct and suitable for further operations; the second being to automatically import the selection into a selection list for further operations. For the first route, beginning at act 716, the selection including at least one component sharing common shape elements with the seed component to the user. The seed component itself may also be displayed at the same time. At act 718, an optional filtering step takes place, where the seed component and/or the selection is filtered based on an independent filter prior to displaying to the user. For example, the user may wish to filter out certain selected components from the selection that is displayed based on certain preferences or may require that the final selection does not display the seed component. The acts of displaying the seed component and/or the at least one component ideally take place via a graphical control element displayed to the user. This may be a dialog box, window, menu, icon, or other element in the graphical display shown to the user. It may be desirable to have the selection of at least one component in a ready-to-view display, such as by pre-populating the graphical control element. At act 720, a confirmation of the selection of at least one component by the user is received, and at act 722, the selected at least one component is added to a selection list for further operations within the CAD model. Alternatively, if the second route is chosen, at act 724, the selected at least one component is added to a selection list for further operations within the CAD model. This is done directly without further input from the user other than the initial seed component selection. The seed component is displayed via a graphical control element displayed to the user. This may be a dialog box, window, menu, icon, or other element in the graphical display shown to the user. For use in CAD applications where shapes are described within the CAD model as n-dimensional vectors, typically n=30.

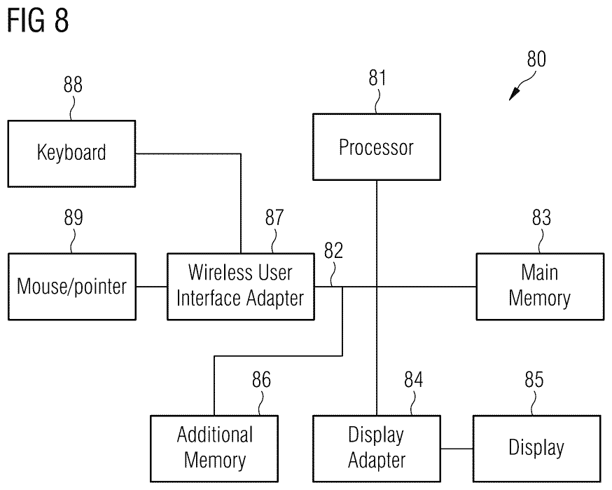

FIG. 8 illustrates an example of a data processing system in which an embodiment of the present disclosure may be implemented (e.g., a CAD application configured to perform the methods of the embodiments as described herein). The data processing system 80 includes a processor 81 connected to a local system bus 82. The local system bus 82 connects the processor to a main memory 83 and graphics display adaptor 84, which may be connected to a display 85. The data processing system 80 may communicate with other systems via a wireless user interface adapter connected to the local system bus 82, or via a wired network, for example, to a local area network. Additional memory 86 may also be connected via the local system bus 82. A suitable adaptor, such as a wireless user interface adapter 87, for other peripheral devices, such as a keyboard 88 and a mouse 89, or other pointing device, allows the user to provide input to the data processing system. Other peripheral devices may include one or more I/O controllers such as USB controllers, Bluetooth controllers, and/or dedicated audio controllers (e.g., connected to speakers and/or microphones). Various peripherals may be connected to the USB controller (e.g., via various USB ports), including input devices (e.g., keyboard, mouse, touch screen, trackball, camera, microphone, scanners), output devices (e.g., printers, speakers), or any other type of device that is operative to provide inputs or receive outputs from the data processing system. Further, many devices referred to as input devices or output devices may both provide inputs and receive outputs of communications with the data processing system. Further, other peripheral hardware connected to the I/O controllers may include any type of device, machine, or component that is configured to communicate with a data processing system.

An operating system included in the data processing system enables an output from the system to be displayed to the user on the display 85 and the user to interact with the system. Examples of operating systems that may be used in a data processing system may include Microsoft Windows™, Linux™, UNIX™, iOS™, and Android™ operating systems.

In addition, data processing system 80 may be implemented as in a networked environment, distributed system environment, virtual machines in a virtual machine architecture, and/or cloud environment. For example, the processor 21 and associated components may correspond to a virtual machine executing in a virtual machine environment of one or more servers. Examples of virtual machine architectures include VMware ESCi, Microsoft Hyper-V, Xen, and KVM.

Those of ordinary skill in the art will appreciate that the hardware depicted for the data processing system 80 may vary for particular implementations. For example, the data processing system 80 in this example may correspond to a computer, workstation, and/or a server. However, alternative embodiments of a data processing system may be configured with corresponding or alternative components such as in the form of a mobile phone, tablet, controller board, or any other system that is operative to process data and carry out functionality and features described herein associated with the operation of a data processing system, computer, processor, and/or a controller discussed herein. The depicted example is provided for the purpose of explanation only and is not meant to imply architectural limitations with respect to the present disclosure.

The data processing system 80 may be connected to the network (not a part of da-ta processing system 80), which may be any public or private data processing system network or combination of networks, as known to those of skill in the art, including the Internet. The data processing system 80 may communicate over the network with one or more other data processing systems such as a server (also not part of the data processing system 80). However, an alternative data processing system may correspond to a plurality of data processing systems implemented as part of a distributed system in which processors associated with a number of (e.g., several) data processing systems may be in communication via one or more network connections and may collectively perform tasks described as being performed by a single data processing system. Thus, when referring to a data processing system, such a system may be implemented across a number of (e.g., several) data processing systems organized in a distributed system in communication with each other via a network. The data processing system 80 is configured to carry out the methods in accordance with the embodiments described below. For example, the keyboard 88 and mouse 89 may function as a user input device for receiving information from the user, the processor 81 may be configured to carry out the acts of the method, and the display 85 may be configured to display a particular view to the user. A computer product including instructions that, when run on a computer, such as the data processing system 80, may be provided to cause the computer to execute the acts of the methods of the embodiments outlined above.

The embodiments described herein therefore offer the ability for a user to quickly and simply select similar components for further processing when working on a design within a CAD application.

While the present disclosure has been described in detail with reference to certain embodiments, the present disclosure is not limited to those embodiments. In view of the present disclosure, many modifications and variations would present themselves, to those skilled in the art without departing from the scope of the various embodiments of the present disclosure, as described herein. The scope of the present disclosure is, therefore, indicated by the following claims rather than by the foregoing description. All changes, modifications, and variations coming within the meaning and range of equivalency of the claims are to be considered within the scope.

It is to be understood that the elements and features recited in the appended claims may be combined in different ways to produce new claims that likewise fall within the scope of the present disclosure. Thus, whereas the dependent claims appended below depend from only a single independent or dependent claim, it is to be understood that these dependent claims may, alternatively, be made to depend in the alternative from any preceding or following claim, whether independent or dependent, and that such new combinations are to be understood as forming a part of the present specification.

1. A method of enabling a user to select at least one component from a group comprising identical, non-identical, or identical and non-identical components forming part of a computer-aided design (CAD) model, the method being computer-implemented and comprising:
receiving a seed component selection from a user via a user input device, the seed component representing component criteria desired by the user; and
based on the seed component, generating a selection comprising at least one component sharing common shape elements with the seed component,
wherein generating the selection comprises:
clustering the group of identical, non-identical, or identical and non-identical components into clusters Cₙ using a first hyperparameter value kₘ₌₁, wherein kₘϵ [symbol] and kₘ≠1, in a clustering algorithm, wherein each of the cluster Cₙ has a stability Sₙ and a component density Δₙ, and wherein the clustering algorithm is a hierarchical clustering algorithm and generates an initial dendrogram of clusters based on the hyperparameter kₘ, wherein each node in the initial dendrogram of clusters represents a cluster of components;
selecting a subset of the clusters Cₘ, the selecting comprising flattening the initial dendrogram of clusters, such that a non-overlapping clustering is produced;
calculating a validity index ψ₁ for the first hyperparameter value k₁, the validity index ψ₁ being proportional to a sum over the subset of clusters of an integral of 1/λ over each of the components in each of the selected clusters;
generating a set of clusterings {Cₘ} for a set of m values of the hyperparameter kₘ and the associated validity indexes, the generating of the set of clusterings comprising repeating the clustering, the selecting, and the calculating;
choosing the clustering of the set of clusterings for which kₘ=argmaxₘ({ψₘ}) as the basis of a selection comprising at least one component sharing common shape elements with the seed component; and
matching a cluster from the clustering to the seed component for display as the selection comprising at least one component sharing common shape elements with the seed component.

2. The method of claim 1, wherein selecting the subset of clusters comprises:
condensing the initial dendrogram of clusters Cₙ into a simplified dendrogram having a reduced number of clusters Cᵣ; and
flattening the simplified dendrogram to select the subset of clusters Cₘ using an excess of mass algorithm, wherein the reduced number of clusters Cᵣ is determined by a minimum cluster size J indicating a minimum number j of components within each cluster.

3. The method of claim 2, wherein the stability Sᵣ of a cluster Cᵣ in the reduced clustering is given by:
$${S}_{r} = {\sum }_{{c}_{j} ϵ {C}_{r}} ( {λ}_{max} ( {c}_{j} , {C}_{r} ) - {λ}_{min} ( {C}_{r} ) )$$
where λₘₐₓ(cⱼ, Cᵣ) is a density level beyond which a component cⱼ is no longer part of the cluster Cᵣ, and λₘᵢₙ(Cᵣ) is a minimum density level at which the cluster Cᵣ exists.

4. The method of claim 3, wherein calculating the validity index ψₘ comprises calculating:
$${ψ}_{m} = \frac{1}{NH} {\sum }_{p ϵ {C}_{m}} ( {\sum }_{j {ϵΦ}_{p}} {ε}_{j} )$$
wherein Φₚ represents a dendrogram node that corresponds to a cluster in Cₘ, N is a number of components in the group, H is a height of the dendrogram, and εⱼ=1/λⱼ for each of the j components in a cluster.

5. The method of claim 1, wherein the hierarchical clustering algorithm is HDBSCAN.

6. The method of claim 1, further comprising:
displaying the seed component, the selection comprising at least one component sharing common shape elements with the seed component, or the seed component and the selection comprising the at least one component sharing common shape elements with the seed component to the user.

7. The method of claim 6, further comprising:
filtering the seed component, the selection, or the seed component and the selection based on an independent filter prior to displaying to the user.

8. The method of claim 6, wherein displaying the seed component, the at least one component, or the seed component and the at least one component takes place via a graphical control element displayed to the user.

9. The method of claim 8, wherein displaying the selection comprising the at least one component comprises pre-populating the graphical control element.

10. The method of claim 6, further comprising:
receiving a confirmation of the selection of at least one component by the user; and
adding the selected at least one component to a selection list for further operations within the CAD model.

11. The method of claim 1, further comprising:
adding the selected at least one component to a selection list for further operations within the CAD model.

12. The method of claim 1, wherein shapes of the components are described as n-dimensional vectors.

13. (canceled)

14. A data-processing system configured to enable a user to select at least one component from a group comprising identical, non-identical, or identical and non-identical components forming part of a computer-aided design (CAD) model, the data-processing system comprising:
a user input device configured to receive a seed component selection from a user, the seed component representing component criteria desired by the user; and
a processor configured to generate, based on the seed component, a selection comprising at least one component sharing common shape elements with the seed component,
wherein the processor being configured to generate the selection comprises the processor being configured to:
cluster the group of identical, non-identical, or identical and non-identical components into clusters Cₙ using a first hyperparameter value kₘ₌₁, wherein kₘϵ [symbol] and kₘ≠1, in a clustering algorithm, wherein each of the clusters Cₙ has a stability Sₙ and a component density λₙ, and wherein the clustering algorithm is a hierarchical clustering algorithm and generates an initial dendrogram of clusters based on the hyperparameter kₘ, wherein each node in the initial dendrogram of clusters represents a cluster of components;
select a subset of the clusters Cₘ by flattening the initial dendrogram of clusters to produce a non-overlapping clustering;
calculate a validity index ψ₁ for the first hyperparameter k₁, the validity index ψ₁ being proportional to a sum over the subset of clusters of an integral of 1/λ over each of the components in each of the selected clusters;
select a set of clusterings {Cₘ} for a set of m values of the hyperparameter kₘ and the associated validity indexes by repeating the cluster, the selection, and the calculation;
choose the clustering for which kₘ=argmaxₘ({ψₘ}) as the basis of a selection comprising at least one component sharing common shape elements with the seed component; and
match a cluster from the clustering to the seed component for display as the selection comprising at least one component sharing common shape elements with the seed component.

15. The data-processing system of claim 14, further comprising a display configured to display the seed component, selection of at least one component, or the seed component and the selection of the at least one component to the user.
